(19) United States
(12) Patent Application Publication
(10) Pub. No.: US 2022/0239126 A1
(43) Pub. Date: Jul. 28, 2022

(54) Outdoor Box, System and Use of an Outdoor Box and/or a System

(71) Applicant: Andreas Stihl AG & Co. KG, Waiblingen (DE)

(72) Inventors: Friedhelm KOCH, Allmersbach im Tal (DE); Joana SCHIERLING, Fellbach (DE); Christian SCHMID-SCHOENBEIN, Stuttgart (DE); Simon GABLER, Marbach (DE)

(21) Appl. No.: 17/586,352

(22) Filed: Jan. 27, 2022

(30) Foreign Application Priority Data
Jan. 28, 2021 (EP) 21154052.1

(51) Int. Cl. H02J 7/00; H01M 50/204; G05D 23/19; H05K 7/20

(52) U.S. Cl. CPC H02J 7/0045; H01M 50/204; H05K 7/20209; G05D 23/1951; H05K 7/20136; G05D 23/1931

(57) ABSTRACT

An outdoor box is designed for keeping at least one battery pack that supplies an electrically driven garden, forestry, construction and/or ground working apparatus with electrical driving power. The outdoor box is configured to receive at least one charger for supplying the battery pack with electrical charging power. The outdoor box has an electrical line for transmission of electrical power to the charger. The outdoor box has an exchange fan for exchange of outside air outside the outdoor box and inside air inside the outdoor box in contact with the battery pack and/or the charger. The outdoor box has a recirculation fan, different from the exchange fan, for recirculating, inside the outdoor box, the inside air, and/or the outdoor box has a further exchange fan for exchange of the outside air and the inside air. The one exchange fan is designed for being supplied with electrical power at least for the most part by an energy source. The further exchange fan is designed for being supplied with electrical power at least for the most part by a further energy source, different from the energy source.

### CROSS REFERENCE TO RELATED APPLICATION

This application claims priority under 35 U.S.C. § 119 from European Patent Application No. 21154052.1, filed Jan. 28, 2021, the entire disclosure of which is herein expressly incorporated by reference.

### BACKGROUND AND SUMMARY OF THE INVENTION

The invention relates to an outdoor box, to a system having such an outdoor box and to a use of such an outdoor box and/or such a system.

The invention addresses the problem of providing an outdoor box that has improved properties, in particular makes possible a simple and/or, in particular consequently, robust structure and/or simple and/or more independent operation of the outdoor box, in particular for charging a battery pack, providing a system having such an outdoor box and providing a use of such an outdoor box and/or such a system.

The outdoor box according to the invention is designed or configured for keeping at least one battery pack for supplying an electrically driven garden, forestry, construction and/or ground working apparatus with electrical driving power. Furthermore, the outdoor box is designed or configured at least for receiving at least one, electrical, charger for, in particular automatically, supplying the battery pack with electrical charging power. Furthermore, the outdoor box comprises or has an electrical line for the, in particular automatic and/or electrical, transmission or for the transport of electrical energy to the charger. Furthermore, the outdoor box comprises or has an, in particular first and/or electrical, exchange or fresh-air fan for the, in particular automatic and/or direct, exchange of outside or fresh air outside the outdoor box and inside air inside the outdoor box in contact or, in particular direct contact, with or flowing along the battery pack and/or the charger.

In addition, the outdoor box comprises or has an, in particular electrical, recirculation fan, different from the exchange fan, for the, in particular automatic and/or direct, recirculation inside the outdoor box of the, in particular same or present, inside air. Also in addition or as an alternative, the outdoor box comprises or has a further, in particular second and/or electrical, exchange fan for the, in particular automatic and/or direct, exchange of the outside air and the, in particular same or present, inside air. The one exchange fan is designed or configured for being supplied, in particular automatically, or the outdoor box is designed or configured for supplying the one exchange fan with electrical power at least for the most part, in particular entirely or completely or only, by an, in particular first and/or electrical, energy source. The further exchange fan is designed or configured for being supplied, in particular automatically, or the outdoor box is designed or configured for supplying the further exchange fan with electrical power at least for the most part, in particular entirely or completely or only, by a further, in particular second and/or electrical, energy source that is, in particular completely, different from the energy source.

In particular, the garden, forestry, construction and/or ground working apparatus may be exposed to environmental or external influences, in particular cold and/or heat and/or moisture and/or dirt.

This, in particular the keeping of the battery pack and/or at least the receiving of the charger in the outdoor box, makes it possible for the battery pack and/or the charger to be protected by the outdoor box from the environmental influences.

In particular, the outdoor box can be exposed to the environmental influences.

In addition or as an alternative, this makes it possible in particular for the outdoor box to charge the battery pack by the charger, in particular while it is protected from environmental influences by the outdoor box.

In particular, it may be required or necessary for the charging that an inside temperature of the inside air, in particular at the battery pack and/or the charger, reaches and/or goes above a minimum temperature value and/or reaches and/or goes below a maximum temperature value. In addition or as an alternative, the charging may produce waste heat.

Also in addition or as an alternative, this makes possible, in particular the, in particular one, exchange fan and the recirculation fan and/or the further exchange fan make possible an, in particular required or necessary, influencing, in particular setting, of the inside temperature of the inside air, in particular at the battery pack and/or the charger. In particular, this is made possible by the exchange of, in particular suitably, cooler outside air, and, in particular unsuitably, warm or hot inside air, and/or by the recirculation of the inside air, in particular with a suitable inside temperature.

Also in addition, this, in particular the outdoor box having the, in particular one, exchange fan and the recirculation fan, makes possible the exchange and/or the recirculation, or both of these, in particular different, functions, without an air flap, in particular that has to be operated. In addition or as an alternative, the, in particular respective, supply provided by the different energy sources makes possible greater operational readiness, or greater independence for the exchange. Consequently, this makes possible a simple and/or, in particular consequently, robust structure and/or simple and/or more independent operation of the outdoor box.

In particular, the outdoor box may be a box for use outside and/or outdoors. In addition or as an alternative, the outdoor box may be substantially or approximately, in particular exactly, cuboidal.

The outdoor box may be designed for the time-limited keeping or for the removable keeping or removal of at least the battery pack. In addition or as an alternative, at least the battery pack may be kept or, in particular spatially, arranged, in particular completely, in the outdoor box.

The battery pack, in particular when removed or not being kept, may be designed for supplying the garden, forestry, construction and/or ground working apparatus with electrical driving power. In addition or as an alternative, the garden, forestry, construction and/or ground working apparatus may be hand-guided, in particular hand-carried. In particular, a hand-guided, in particular hand-carried, garden, forestry, construction and/or ground working apparatus may mean that the garden, forestry, construction and/or ground working apparatus can comprise or have a mass of a maximum of 50 kilograms (kg), in particular of a maximum of 20 kg, in particular of a maximum of 10 kg. Also in addition or as an alternative, the garden, forestry, construction and/or ground working apparatus may be a saw, in particular a chainsaw, or a pole-mounted pruner, or a hedge trimmer, or a hedge cutter, or a woodcutter, or a lopper, or a blower, or a leaf blower, or a suction device, or a leaf vacuum, or a cleaning device, or a high-pressure cleaner, or a sweeping roller, or a sweeping brush, or a lawnmower, in particular a lawnmowing robot, or a brush cutter, or a scarifier, or an angle grinder, or a stone cutter. Also in addition or as an alternative, the garden, forestry, construction and/or ground working apparatus may have an electric drive motor.

The outdoor box may be designed for receiving at least the charger for a sustained period of time. In addition or as an alternative, at least the charger may be received or, in particular spatially, arranged, in particular completely, in the outdoor box.

The charger, in particular when received, may be designed for supplying the, in particular kept, battery pack with electrical charging power.

The electrical line may be designed for the transmission of electrical power to the, in particular received, charger, in particular for supplying the, in particular kept, battery pack with electrical charging power by the charger. In addition or as an alternative, the electrical line may be integrated, in particular permanently, in the outdoor box. Also in addition or as an alternative, the electrical line may be an electrical installation.

The, in particular one, exchange fan, and/or the recirculation fan and/or the further exchange fan need not be, in particular in each case, part of the charger. In addition or as an alternative, the, in particular one, exchange fan, and/or the recirculation fan and/or the further exchange fan, may be, in particular in each case, integrated, in particular permanently, in the outdoor box.

The inside air may be in contact with the kept battery pack and/or the received charger.

The recirculation may be different from the exchange. In addition or as an alternative, the recirculation fan may be designed, in particular arranged and/or aligned, for the exchange of the outside air and the inside air, in particular with an exchanged air mass, of a maximum of 0.2 times, in particular a maximum of 0.1 times, the recirculation of the inside air, in particular with a recirculated air mass, or even no exchange or without exchange of the outside air and the inside air.

At least for the most part may mean more than 50% (percent), in particular a minimum of 60%, in particular a minimum of 70%, in particular a minimum of 80%, in particular a minimum of 90%, in particular a minimum of 95%, in particular a minimum of 99%, of the electrical power and/or of a time. In addition or as an alternative, the one exchange fan need not be designed for being supplied or the outdoor box need not be designed for supplying the one exchange fan with electrical power by the further energy source. Also in addition or as an alternative, the further exchange fan need not be designed for being supplied or the outdoor box need not be designed for supplying the further exchange fan with electrical power by the one energy source. Also in addition or as an alternative, the recirculation fan may be designed for being supplied, in particular automatically, or the outdoor box may be designed for supplying the recirculation fan with electrical power at least for the most part, in particular entirely or completely or only, by the further energy source.

The electrical line may be designed for the, in particular automatic and/or electrical, transmission of electrical power to the recirculation fan and/or the further exchange fan, in particular be electrically connected, in particular permanently, to it/them. In addition or as an alternative, the electrical line need not be designed for the transmission of electrical power to the one exchange fan, in particular not electrically connected to it.

In a development of the invention, the outdoor box is designed or configured as a transporting outdoor box and/or a mobile outdoor box. In addition or as an alternative, the outdoor box is designed or configured for arranging, in particular for fastening, on an, in particular open, loading area, in particular a loading platform, of a vehicle, in particular a motor vehicle. This makes simple transporting of the battery pack and/or the charger possible. In particular, the outdoor box can be exposed to the environmental influences when the vehicle is, in particular parked, outside or outdoors. In addition or as an alternative, the outdoor box may be a platform box.

In a development of the invention, the outdoor box comprises or has the charger. In particular, the charger may be integrated, in particular permanently, in the outdoor box. In addition or as an alternative, the electrical line may be electrically connected, in particular permanently, to the charger. Also in addition or as an alternative, the charger may be designed for being supplied, in particular automatically, or the outdoor box may be designed for supplying the charger with electrical power at least for the most part, in particular entirely or completely or only, by the further energy source.

In a development of the invention, the electrical line comprises or has an electricity mains connection, in particular a mains plug. In particular, the electrical line is designed or configured for the, in particular automatic and/or electrical, transmission or for the transport of electrical power from the electricity connection to the recirculation fan and/or the further exchange fan. This makes it possible to provide a supply with electrical power from an external, in particular public, power grid. In particular, the external power grid may have, in particular be, the further energy source. In addition or as an alternative, the power grid may be a low-voltage grid, in particular of 100 volts (V) to 1000 V, in particular of 100 V to 127 V or 220 V to 240 V or 400 V. Also in addition or as an alternative, the electricity connection may be a low-voltage electricity connection, in particular a 100 V to 127 V and/or 220 V to 240 V or 400 V electricity connection.

In a development of the invention, the outdoor box comprises or has an, in particular direct and/or electrical, radiation-energy conversion device, in particular a solar cell, for supplying, in particular automatically, in particular for operating, in particular automatically, the, in particular one, exchange fan, in particular independently of and uncontrolled by an inside temperature, in particular a value of the inside temperature, of the inside air and/or an outside temperature, in particular a value of the outside temperature, of the outside air, with electrical power. This makes it possible when there is radiation, in particular when there is solar radiation, and generally consequently when the inside air is, in particular unsuitably, warm or hot, to exchange the, in particular suitably, cooler outside air and the, in particular unsuitably, warm or hot inside air. In particular, this makes possible a particularly simple and/or, in particular consequently, particularly robust structure of the outdoor box. In particular, the one energy source may have, in particular be, the radiation-energy conversion device. In addition or as an alternative, the radiation-energy conversion device may be a solar-energy conversion device. Also in addition or as an alternative, the radiation-energy conversion device may be electrically connected, in particular permanently, to the exchange fan. Also in addition or as an alternative, the, in particular one, exchange fan may be a solar fan. Also in addition or as an alternative, the radiation-energy conversion device may be integrated, in particular permanently, in the outdoor box.

In a development, in particular an embodiment, of the invention, the outdoor box comprises or has an electrical energy store, in particular a battery, for supplying, in particular automatically, in particular for operating, in particular automatically, the, in particular one, exchange fan, in particular independently of and uncontrolled by an inside temperature, in particular a value of the inside temperature, of the inside air and/or an outside temperature, in particular a value of the outside temperature, of the outside air, with electrical power, in particular from the radiation-energy conversion device, if present. This makes possible a particularly greater operational readiness or a particularly greater independence for the exchange, in particular if the sun is covered or even is not shining. In particular, this makes possible a particularly simple and/or, in particular consequently, particularly robust structure of the outdoor box. In particular, the one energy source may have, in particular be, the electrical energy store. In addition or as an alternative, the electrical energy store may be, in particular designed as, chargeable. Also in addition or as an alternative, the electrical energy store may be designed for feeding electrical power not required by the, in particular one, exchange fan through the radiation-energy conversion device, in particular when there is a lot of radiation. Furthermore, the electrical energy store may be designed for feeding or providing electrical power required by the, in particular one, exchange fan, in particular when there is not much or even no radiation. Also in addition or as an alternative, the battery may be electrically connected, in particular permanently, to the, in particular one, exchange fan, in particular and the radiation-energy conversion device. Also in addition or as an alternative, the electrical energy store may be a buffer store. Also in addition or as an alternative, the electrical energy store may be integrated, in particular permanently, in the outdoor box.

In a development, in particular an embodiment, of the invention, the outdoor box comprises or has a box container or body and a box lid. The box container is designed or configured for keeping the battery pack and at least for receiving the charger. In particular, the electrical line and/or the recirculation fan and/or the further exchange fan are/is arranged, in particular fastened, in particular directly, on the box container. For opening and closing, in particular locking, the box container, the box lid is, in particular designed as, movable with respect to it, in particular by a person or a user. The, in particular one, exchange fan, in particular and the radiation-energy conversion device and/or the electrical energy store, if present, is, in particular are, arranged, in particular fastened, in particular directly, on the box lid. This makes possible the keeping, in particular and the removal, of the battery pack and/or the receiving of the charger, in particular when the box container is open or not closed. In addition or as an alternative, this makes it possible that the electrical line need not lead from the box container to the box lid. In particular, the box lid may be movably arranged, in particular fastened, on the box container by means of a hinge. In addition or as an alternative, the charger and/or the electrical line and/or the recirculation fan and/or the further exchange fan may be, in particular in each case, integrated, in particular permanently, in the box container. Also in addition or as an alternative, the, in particular one, exchange fan and/or the radiation-energy conversion device and/or the electrical energy store may be, in particular in each case, integrated, in particular permanently, in the box lid.

In a development, in particular an embodiment, of the invention, the outdoor box has or comprises at least one air inlet opening for letting the outside air into the outdoor box and at least one air outlet opening for letting the inside air out of the outdoor box. The air outlet opening is in particular arranged above with respect to the air inlet opening in a vertical direction from an underside to an upper side of the outdoor box, in particular and offset in a horizontal direction orthogonal to the vertical direction, in particular when the outdoor box is in the alignment or position or location as intended and/or when the outdoor box is closed. In particular, the air outlet opening is in particular arranged on, in particular in, the upper side, in particular the box lid, if present. In addition or as an alternative, the air inlet opening is in particular arranged on, in particular in, the underside and/or a peripheral side of the outdoor box, in particular the box container, if present. This makes possible a particularly good exchange of the, in particular warm or hot, inside air, in particular and a flow of the inside air at least partially in the horizontal direction. In particular, the air inlet opening and/or the air outlet opening may be defined, in particular in each case, by a direction of an air flow, in particular delivered by the, in particular one, exchange fan and/or the further exchange fan. In addition or as an alternative, the upper side may be opposite from the underside. Also in addition or as an alternative, the peripheral side may be, in particular in each case, averted from the underside and/or the upper side and/or, in particular in the vertical direction, may be between the underside and the upper side.

In a development of the invention, the outdoor box has or comprises at least one, in particular the, air inlet opening for letting the outside air into the outdoor box and/or at least one, in particular the, air outlet opening for letting the inside air out of the outdoor box. The outdoor box is designed or configured for keeping the battery pack and/or at least for receiving the charger in relation to the air inlet opening and/or the air outlet opening above in a, in particular the, vertical direction from an, in particular the, underside to an, in particular the, upper side of the outdoor box, and/or offset in a, in particular the, horizontal direction orthogonal to the vertical direction, in particular when the outdoor box is in the alignment or position or location as intended and/or when the outdoor box is closed. This makes possible particularly good protection of the battery pack and/or the charger by the outdoor box from the environmental influences, in particular from moisture and/or dirt. In particular, the air inlet opening and/or the air outlet opening may be defined, in particular in each case, by a direction of an air flow, in particular delivered by the, in particular one, exchange fan and/or the further exchange fan. In addition or as an alternative, the upper side may be opposite from the underside. Also in addition or as an alternative, the air inlet opening and/or the air outlet opening may extend, in particular in each case, substantially or approximately, in particular exactly, in the horizontal direction.

In a development of the invention, the outdoor box has or comprises at least one, in particular the, air inlet opening for letting the outside air into the outdoor box and/or at least one, in particular the, air outlet opening for letting the inside air out of the outdoor box. The, in particular one, exchange fan and/or the further exchange fan are/is in particular arranged on, in particular in, the air inlet opening or the air outlet opening, and are/is at an, in particular respective, exchange distance from this, in particular closest, opening along an, in particular respective, air flow path. A recirculation distance, in particular a value of the recirculation distance, of the recirculation fan along an, in particular own, air flow path is from the, in particular closest, air inlet opening and/or the, in particular closest, air outlet opening greater than the exchange distance, in particular the value of the exchange distance, in particular when the outdoor box is closed. This makes possible the exchange and the recirculation or both of these, in particular different, functions. In particular, the air inlet opening and/or the air outlet opening may be defined, in particular in each case, by a direction of an air flow, in particular delivered by the, in particular one, exchange fan and/or the further exchange fan. In addition or as an alternative, the exchange distance may be zero.

In a development of the invention, the, in particular one, exchange fan for delivering or producing an air flow, in particular in the exchange fan, is aligned substantially or approximately, in particular exactly, in a first direction, in particular an, in particular the, vertical direction from an, in particular the, underside to an, in particular the, upper side of the outdoor box, in particular when the outdoor box is in the alignment or position or location as intended and/or when the outdoor box is closed. In addition or as an alternative, the recirculation fan for delivering or producing an air flow, in particular in the recirculation fan, is aligned substantially or approximately, in particular exactly, in a second direction, in particular an, in particular the, horizontal direction and/or different from, in particular orthogonal to, the first direction, in particular when the outdoor box is in the alignment or position or location as intended and/or when the outdoor box is closed. Also in addition or as an alternative, the further exchange fan for delivering or producing an air flow, in particular in the exchange fan, is aligned substantially or approximately, in particular exactly, in a third direction, in particular an, in particular further, horizontal direction and/or different from, in particular orthogonal to, the first direction and/or the second direction, in particular when the outdoor box is in the alignment or position or location as intended and/or when the outdoor box is closed. This makes possible the exchange and the recirculation, or both of these, in particular different, functions and/or a particularly good exchange by the one exchange fan and the further exchange fan. In particular, the, in particular one, exchange fan, the recirculation fan and/or the further exchange fan may be, in particular in each case, an axial fan, it being possible for an, in particular respective, axial direction of the, in particular respective, axial fan to be substantially, in particular exactly, in the, in particular first, second or third, direction. In addition or as an alternative, substantially may mean deviating a maximum of 30° (degrees), in particular a maximum of 20°, in particular a maximum of 10°, from the, in particular first, second or third, direction.

In a development of the invention, the outdoor box comprises or has an, in particular electrical, heater, in particular a radiator, and/or an, in particular electrical, cooler, in particular a Peltier element. The recirculation fan or the outdoor box is designed or configured for the, in particular automatic and/or direct, recirculation of the inside air along the heater and/or the cooler, in particular flowing along. This makes possible energy-efficient heating and/or cooling of the inside air, in particular since as a result of the recirculation with little or no exchange of the inside air. In particular, the heater and/or the cooler may be designed, in particular in each case, for being supplied, in particular automatically, or the outdoor box may be designed for supplying the heater and/or the cooler, in particular in each case, with electrical power at least for the most part, in particular entirely or completely or only, by the further energy source. In addition or as an alternative, the electrical line may be designed, in particular in each case, for the, in particular automatic and/or electrical, transmission of electrical power to the heater and/or the cooler, in particular be electrically connected, in particular permanently, to it/them. Also in addition or as an alternative, the heater and/or the cooler may be, in particular in each case, integrated, in particular permanently, in the outdoor box.

In a development, in particular an embodiment, of the invention, the outdoor box comprises or has an, in particular electrical, open-loop and/or closed-loop control device for the, in particular automatic, open-loop and/or closed-loop control of, in particular respective, operation of the recirculation fan, in particular and of the heater and/or the cooler, if present, and/or of the further exchange fan dependent on an, in particular the, inside temperature, in particular a value of the inside temperature, in particular detected by means of an, in particular electrical, inside temperature sensor of the outdoor box, of the inside air and/or an, in particular the, outside temperature, in particular a value of the outside temperature, in particular detected by means of an, in particular electrical, outside temperature sensor of the outdoor box, of the outside air. In particular in such a way that the inside temperature reaches and/or goes above an, in particular the, minimum temperature value and/or reaches and/or goes below an, in particular the, maximum temperature value. This makes possible particularly good influencing, in particular setting, in particular of the inside temperature. In particular, the open-loop and/or closed-loop control device may be electrically connected to the recirculation fan, the heater, the cooler, the further exchange fan, the inside temperature sensor and/or the outside temperature sensor. In addition or as an alternative, the open-loop and/or closed-loop control device may be designed for being supplied, in particular automatically, or the outdoor box may be designed for supplying the open-loop and/or closed-loop control device with electrical power at least for the most part, in particular entirely or completely or only, by the further energy source. Also in addition or as an alternative, the electrical line may be designed for the, in particular automatic and/or electrical, transmission of electrical power to the open-loop and/or closed-loop control device, in particular be electrically connected, in particular permanently, to it. Also in addition or as an alternative, the open-loop and/or closed-loop control device, the inside temperature sensor and/or the outside temperature sensor may be, in particular in each case, integrated, in particular permanently, in the outdoor box.

The system according to the invention comprises or has an, in particular the, outdoor box as mentioned above and the battery pack and/or the charger and/or the garden, forestry, construction and/or ground working apparatus and/or the vehicle.

The use according to the invention is an, in particular automatic, use of an, in particular the, outdoor box as mentioned above and/or of an, in particular the, system as mentioned above for, in particular automatically, supplying the, in particular kept, battery pack with electrical charging power by the, in particular received, charger. The use can make possible some or even all of the advantages as above for the outdoor box.

Further advantages and aspects of the invention emerge from the claims and from the description of exemplary embodiments of the invention, which are explained below on the basis of the figures.

### BRIEF DESCRIPTION OF THE DRAWINGS

FIG. 1 shows a schematic sectional view of an outdoor box according to an embodiment of the invention and a use according to an embodiment of the invention of the outdoor box.

FIG. 2 shows a further schematic sectional view of the outdoor box of FIG. 1.

FIG. 3 shows a schematic perspective view of a system according to an embodiment of the invention having the outdoor box of FIG. 1 and a use of the outdoor box and/or of the system, in particular when the outdoor box is closed.

FIG. 4 shows a further schematic perspective view of the system of FIG. 3, in particular when the outdoor box is open.

FIG. 5 shows schematic variations over time of an inside temperature of an inside air and a state of charge of a battery pack in the case of a use not according to the invention of an outdoor box not according to the invention, in particular when there is a cold outside temperature of an outside air.

FIG. 6 shows further schematic variations over time of an inside temperature of an inside air and a state of charge of a battery pack in the case of the use according to an embodiment of the invention, in particular, of the outdoor box of FIG. 1, in particular when there is a cold outside temperature of an outside air.

FIG. 7 shows further schematic variations over time of an inside temperature of an inside air and a state of charge of a battery pack in the case of a use not according to the invention of an outdoor box not according to the invention, in particular when there is a warm outside temperature of an outside air.

FIG. 8 shows further schematic variations over time of an inside temperature of an inside air and a state of charge of a battery pack in the case of the use according to an embodiment of the invention, in particular, of the outdoor box of FIG. 1, in particular when there is a warm outside temperature of an outside air.

### DETAILED DESCRIPTION OF THE DRAWINGS

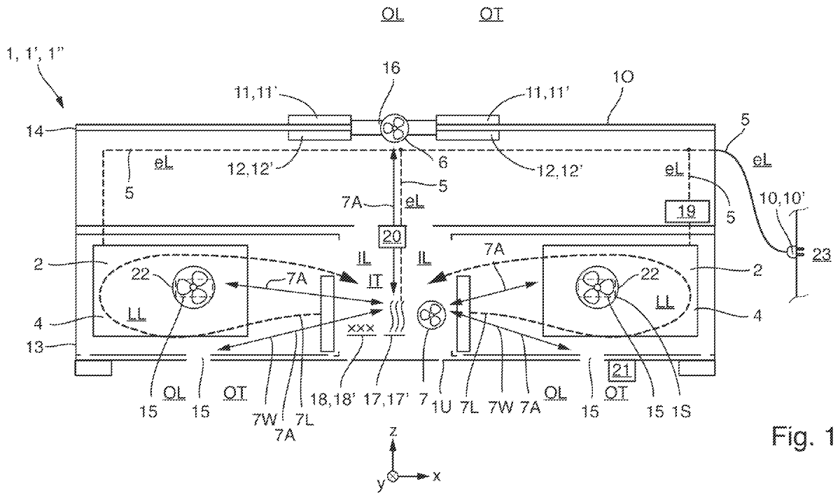

FIGS. 1 to 4 show an outdoor box 1. The outdoor box 1 is designed for keeping, in particular keeps, at least one battery pack 2 for supplying an electrically driven garden, forestry, construction and/or ground working apparatus 3 with electrical driving power AL. Furthermore, the outdoor box 1 is designed at least for receiving, in particular receives, at least one charger 4 for supplying the battery pack with electrical charging power LL. Furthermore, the outdoor box 1 has an electrical line 5 for the transmission of electrical power eL to the charger 4. Also, the outdoor box 1 has an exchange fan 6 for the exchange of outside air OL outside the outdoor box 1 and inside air IL inside the outdoor box 1 in contact with the battery pack 2 and/or the charger 4.

In addition, the outdoor box 1 has a recirculation fan 7, different from the exchange fan 6, for the recirculation inside the outdoor box 1 of the inside air IL.

Also in addition or as an alternative, the outdoor box 1 has a further exchange fan 22 for the exchange of the outside air OL and the inside air IL. The one exchange fan 6 is designed for being supplied with electrical power eL at least for the most part by an energy source 11, 12. The further exchange fan 22 is designed for being supplied with electrical power eL at least for the most part by a further energy source 23, different from the energy source 11, 12.

In alternative exemplary embodiments, the outdoor box may have in addition to the, in particular one, exchange fan either the recirculation fan or the further exchange fan. In particular, if the outdoor box has in addition to the exchange fan, in particular only, the recirculation fan, the exchange fan and the recirculation fan may be designed for being supplied with electrical power at least for the most part by the, in particular same, energy source.

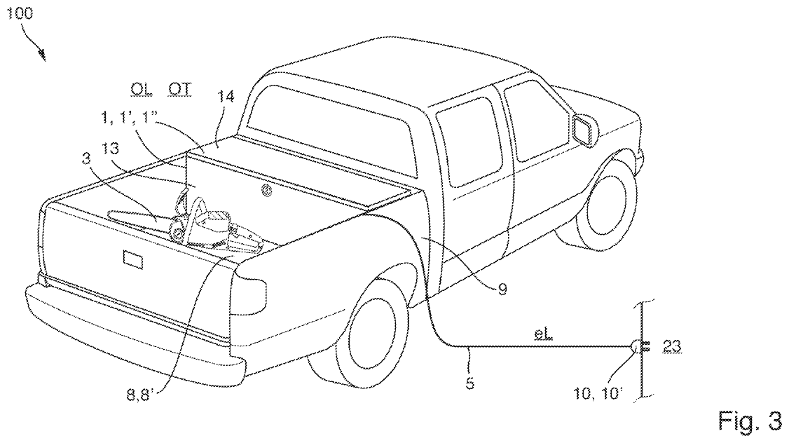

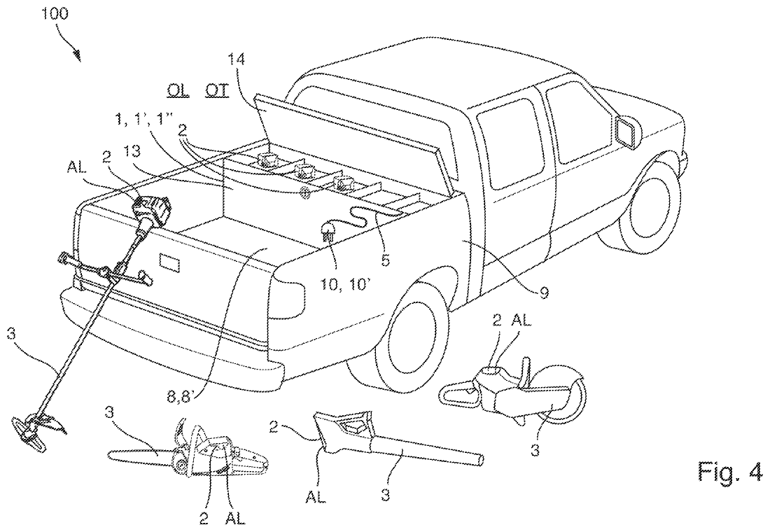

Furthermore, FIGS. 3 and 4 show a system 100 that has the outdoor box 1 and the battery pack 2 and/or the charger 4 and/or the garden, forestry, construction and/or ground working apparatus 3 and/or a vehicle 9.

Furthermore, FIGS. 1 and 3 show a use of the outdoor box 1 and/or of the system 100 for supplying the, in particular kept, battery pack 2 with electrical charging power LL by the, in particular received, charger 4.

In detail, the outdoor box 1 is designed as a transporting outdoor box 1′ and/or a mobile outdoor box 1″.

In addition or as an alternative, the outdoor box is designed, in particular arranged, in particular fastened, for arranging, in particular for fastening, on an, in particular open, loading area 8, in particular a loading platform 8′, of the vehicle 9.

The outdoor box 1 also has the charger 4.

Moreover, the electrical line 5 has an electricity mains connection 10, in particular a mains plug 10′.

In the exemplary embodiment shown, an external power grid has the further energy source 23.

Furthermore, the outdoor box 1 has an, in particular direct, radiation-energy conversion device 11, in particular a solar cell 11′, for supplying, in particular for operating, the, in particular one, exchange fan 6, in particular independently of an inside temperature IT of the inside air IL and/or an outside temperature OT of the outside air OL, with electrical power eL.

In alternative exemplary embodiments, the outdoor box need not have the radiation-energy conversion device.

Furthermore, the outdoor box 1 has an electrical energy store 12, in particular a battery 12′, for supplying, in particular for operating, the, in particular one, exchange fan 6, in particular independently of the inside temperature IT of the inside air IL and/or the outside temperature OT of the outside air OL, with electrical power eL, in particular from the radiation-energy conversion device 11.

In alternative exemplary embodiments, the outdoor box need not have the electrical energy store.

In the exemplary embodiment shown, the one energy source 11, 12 has the radiation-energy conversion device 11 and/or the electrical energy store 12.

The outdoor box 1 also has a box container 13 and a box lid 14. The box container 13 is designed for keeping, in particular keeps, the battery pack 2 and at least for receiving, in particular receives, the charger 4. In particular, the electrical line 5 and/or the recirculation fan 7 and/or the further exchange fan 22 are/is arranged, in particular fastened, on the box container 13. For opening and closing the box container 13, the box lid 14 is movable with respect to it. The, in particular one, exchange fan 6, in particular and the radiation-energy conversion device 11 and/or the electrical energy store 12 is, in particular are, arranged, in particular fastened on the box lid 14.

In alternative exemplary embodiments, the outdoor box need not have a box lid. In addition or as an alternative, in alternative exemplary embodiments, the outdoor box may have at least one box door, in particular on a peripheral side of the outdoor box, in particular of the box container, it being possible for opening and closing the box container for the box door to be, in particular designed as, movable with respect to it. Also in addition or as an alternative, in alternative exemplary embodiments, the, in particular one, exchange fan, in particular and the radiation-energy conversion device and/or the electrical energy store, in particular if present, may be arranged, in particular fastened, on the box container, in particular on an upper side, in particular of the outdoor box.

Moreover, the outdoor box 1 has at least one air inlet opening 15 for letting the outside air OL into the outdoor box 1 and/or at least one air outlet opening 16 for letting the inside air IL out of the outdoor box 1.

In addition, the air outlet opening 16 is with respect to the air inlet opening 15 above in a vertical direction z from an underside 1U to an upper side 1O of the outdoor box 1, in particular and offset in a horizontal direction x orthogonal to the vertical direction z. In particular, the air outlet opening 16 is on, in particular in, the upper side 1O, in particular the box lid 14. In addition or as an alternative, the air inlet opening 15 is on, in particular in, the underside 1U and/or a peripheral side 1S of the outdoor box 1, in particular the box container 13.

Also in addition or as an alternative, the outdoor box 1 is designed for keeping, in particular keeps, the battery pack 2 and/or at least for receiving, in particular receives, the charger 4 in relation to the air inlet opening 15 and/or the air outlet opening 16 above in the vertical direction z from the underside 1U to the upper side 1O of the outdoor box 1 and/or offset in the horizontal direction x orthogonal to the vertical direction z.

Also in addition or as an alternative, the, in particular one, exchange fan 6 and/or the further exchange fan 22 are/is arranged on, in particular in, the air inlet opening 15 or the air outlet opening 16 and are/is at an, in particular respective, exchange distance 6A, 22A from this opening along an, in particular respective, air flow path 6W, 22W. A recirculation distance 7A of the recirculation fan 7 along an, in particular own, air flow path 7W from the air inlet opening 15 and/or the air outlet opening 16 is greater than the exchange distance 6A, 22A.

Furthermore, the, in particular one, exchange fan 6 is aligned for delivering, in particular delivers, an air flow 6L substantially, in particular exactly, in a first direction z, in particular the vertical direction z, from the underside 1U to the upper side 1O of the outdoor box 1. In addition or as an alternative, the recirculation fan 7 is aligned for delivering, in particular delivers, an air flow 7L substantially, in particular exactly, in a second direction x, in particular the horizontal direction x, and/or different from, in particular orthogonal to, the first direction z. Also in addition or as an alternative, the further exchange fan 22 is aligned for delivering, in particular delivers, an air flow 22L substantially, in particular exactly, in a third direction y, in particular an, in particular further, horizontal direction y, and/or different from, in particular orthogonal to, the first direction x and/or the second direction z.

In alternative exemplary embodiments, the, in particular one, exchange fan, the recirculation fan and/or the further exchange fan, may, in particular in each case, deliver in a different direction.

In addition or as an alternative, in alternative exemplary embodiments the, in particular one, exchange fan need not be arranged on the upper side. In particular, the, in particular one, exchange fan may be arranged on the peripheral side.

Furthermore, the outdoor box 1 has a heater 17, in particular a radiator 17′, and/or a cooler 18, in particular a Peltier element 18′. The recirculation fan 7 is designed for the recirculation of the inside air IL along the heater 17 and/or the cooler 18.

Moreover, the outdoor box 1 has an open-loop and/or closed-loop control device 19 for the open-loop and/or closed-loop control of, in particular respective, operation of the recirculation fan 7, in particular and of the heater 17 and/or the cooler 18, and/or of the further exchange fan 22 dependent on the inside temperature IT, in particular detected by means of an inside temperature sensor 20 of the outdoor box 1, of the inside air IL and/or the outside temperature OT, in particular detected by means of an outside temperature sensor 21 of the outdoor box 1, of the outside air OL. In particular in such a way that the inside temperature IT reaches and/or goes above a minimum temperature value Tmin and/or reaches and/or goes below a maximum temperature value Tmax, as shown in FIGS. 6 and 8.

In the exemplary embodiment shown, the charger 4 and/or the recirculation fan 7 and/or the heater 17 and/or the cooler 18 and/or the open-loop and/or closed-loop control device 19 are/is designed, in particular in each case, for being supplied with electrical power eL at least for the most part by the further energy source 23.

Furthermore, in the exemplary embodiment shown, the electrical line 5 is designed for the transmission of electrical power eL from the electricity connection 10 to the charger 4 and/or the recirculation fan 7 and/or the further exchange fan 22 and/or the heater 17 and/or the cooler 18 and/or the open-loop and/or closed-loop control device 19.

In FIGS. 1 and 3, the electrical line 5 transmits electrical power eL, in particular from the electricity connection 10, to the charger 4 and/or the recirculation fan 7 and/or the further exchange fan 22 and/or the heater 17 and/or the cooler 18 and/or the open-loop and/or closed-loop control device 19.

In FIGS. 1 and 3, the charger 4 and/or the recirculation fan 7 and/or the heater 17 and/or the cooler 18 and/or the open-loop and/or closed-loop control device 19 are/is supplied with electrical power eL by the further energy source 23.

Not shown is how the further exchange fan 22 is supplied with electrical power eL by the further energy source 23.

In FIG. 1, the recirculation fan 7 recirculates the inside air IL, in particular along the heater 17 and/or the cooler 18.

Not shown is how the further exchange fan 22 exchanges the outside air OL and the inside air IL.

In FIG. 1, the, in particular received, charger 4 supplies the, in particular kept, battery pack 2 with electrical charging power LL.

In FIG. 4, the battery pack 2, in particular removed or not being kept, supplies the garden, forestry, construction and/or ground working apparatus 3 with electrical driving power AL.

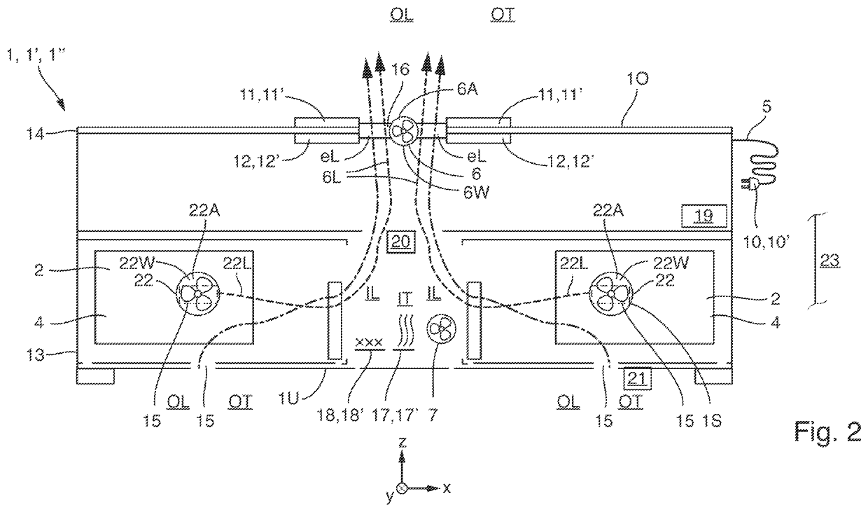

In FIG. 2, the one exchange fan 6 is supplied, in particular operated, with electrical power eL by the one energy source 11, 12, in particular the radiation-energy conversion device 11 and/or the electrical energy store 12.

In FIG. 2, the exchange fan 6 exchanges the outside air OL and the inside air IL.

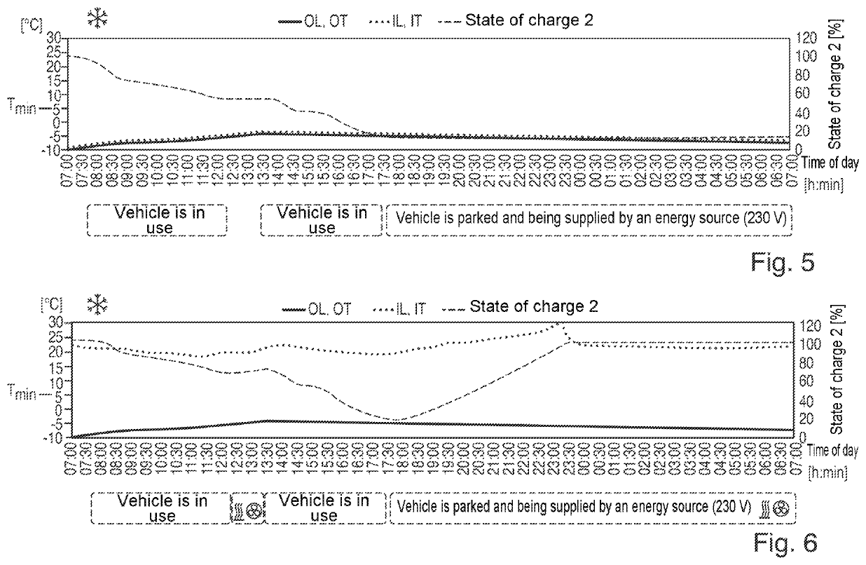

FIG. 5 shows schematic variations over time of an inside temperature IT of an inside air IL and a state of charge of a battery pack 2 in the case of a use not according to the invention of an outdoor box not according to the invention, in particular when there is a cold outside temperature OT of an outside air OL. The vehicle is in use from morning until evening. Consequently, the state of charge of the battery pack 2 falls. From evening until, in particular the next, morning, the vehicle is parked and supplied by an, in particular further, energy source 23. However, the inside temperature IT of the inside air IL goes below the minimum temperature value Tmin, in particular of 5° C. (degrees Celsius). Consequently, charging of the battery pack 2 is not possible. Consequently, the state of charge of the battery pack 2 does not increase.

FIG. 6 shows further schematic variations over time of the inside temperature IT of the inside air IL and the state of charge of the battery pack 2 in the case of the use according to an embodiment of the invention, in particular, of the outdoor box 1 according to an embodiment of the invention, in particular in the case of the cold outside temperature OT of the outside air OL. The vehicle 9 is in use from morning until midday and from midday until evening. Consequently, the state of charge of the battery pack 2 falls. At midday and from the evening until, in particular the next, morning, the vehicle 9 is parked and supplied by the, in particular further, energy source 23. The recirculation fan 7 makes it possible, in particular and the, in particular heating, heater 17 and/or not the exchange fan 6 make it possible that the inside temperature IT reaches and/or goes above the minimum temperature value Tmin, in particular controlled by the open-loop and/or closed-loop control device 19. Consequently, an, in particular complete, charging of the battery pack 2 is possible. Consequently, the state of charge of the battery pack 2 increases, in particular completely.

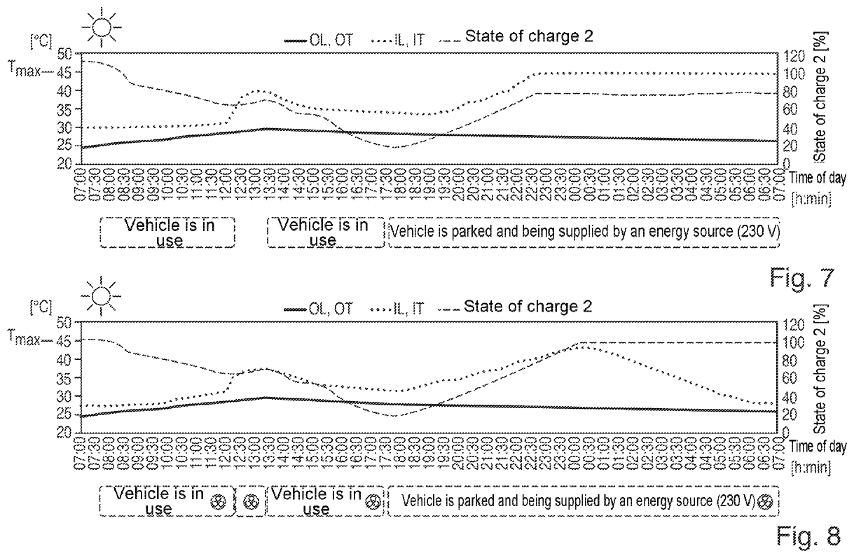

FIG. 7 shows further schematic variations over time of an inside temperature IT of an inside air IL and a state of charge of a battery pack 2 in the case of a use not according to the invention of an outdoor box not according to the invention, in particular when there is a warm outside temperature OT of an outside air OL. The vehicle is in use from morning until evening. Consequently, the state of charge of the battery pack 2 falls. From evening until, in particular the next, morning, the vehicle is parked and supplied by an, in particular further, energy source 23. However, the inside temperature IT of the inside air IL goes above the maximum temperature value Tmax, in particular of 45° C., in particular during the charging of the battery pack 2. Consequently, complete charging of the battery pack 2 is not possible. Consequently, the state of charge of the battery pack 2 does not increase completely.

FIG. 8 shows further schematic variations over time of the inside temperature IT of the inside air IL and the state of charge of the battery pack 2 in the case of the use according to an embodiment of the invention, in particular, of the outdoor box 1 according to an embodiment of the invention, in particular when there is the warm outside temperature OT of the outside air OL. The vehicle 9 is in use from morning until midday and from midday until evening. Consequently, the state of charge of the battery pack 2 falls. At midday and from the evening until, in particular the next, morning, the vehicle 9 is parked and supplied by the, in particular further, energy source 23. The one exchange fan 6 makes it possible, in particular from morning until evening, and/or the recirculation fan 7 and/or the further exchange fan 22, in particular, and the, in particular cooling, cooler 18, make/makes it possible, in particular from evening until, in particular the next, morning, that the inside temperature IT reaches and/or goes below the maximum temperature value Tmax and/or an avoidance or even a prevention of a buildup of heat in the outdoor box 1, in particular controlled by the open-loop and/or closed-loop control device 19. Consequently, an, in particular complete, charging of the battery pack 2 is possible. Consequently, the state of charge of the battery pack 2 increases, in particular completely.

Otherwise, the outdoor box 1 is thermally insulated, in particular on its upper side 1O and/or its peripheral side 1S. This makes stability of the inside temperature IT of the inside air IL possible.

In addition or as an alternative, the outdoor box may be designed for keeping at least two, in particular at least five, in particular at least ten, in particular at least twenty, and/or a maximum of one hundred, in particular a maximum of fifty, in particular twenty-eight, battery packs. Also in addition or as an alternative, the outdoor box may be designed at least for receiving at least two, in particular at least five, and/or a maximum of twenty, in particular a maximum of ten, in particular seven, chargers. Also in addition or as an alternative, the charger may be a multi-compartment charger.

Also in addition or as an alternative, the outdoor box may be a minimum of 50 cm (centimeters), in particular a minimum of 100 cm, and/or a maximum of 400 cm, in particular a maximum of 300 cm, in particular 193 cm, wide, in particular in the horizontal direction x, and/or a minimum of 25 cm, in particular a minimum of 50 cm and/or a maximum of 200 cm, in particular a maximum of 100 cm, in particular 65 cm, deep, in particular in the horizontal direction y, and/or a minimum of 25 cm, in particular a minimum of 50 cm, and/or a maximum of 200 cm, in particular a maximum of 100 cm, in particular 75 cm, high, in particular in the vertical direction z.

As the exemplary embodiments shown and explained above make clear, the invention provides an advantageous outdoor box that has improved properties, in particular makes possible a simple and/or, in particular consequently, robust structure and/or simple and/or more independent operation of the outdoor box, in particular for charging a battery pack, an advantageous system having such an outdoor box and an advantageous use of such an outdoor box and/or such a system.

What is claimed is:

1. An outdoor box for keeping at least one battery pack that supplies an electrically driven garden, forestry, construction and/or ground working apparatus with electrical driving power, wherein the outdoor box is configured at least for receiving at least one charger for supplying the battery pack with electrical charging power, comprising:
an electrical line for transmission of electrical power to the charger;
an exchange fan for exchange of outside air outside the outdoor box and inside air inside the outdoor box in contact with the battery pack and/or the charger; and
at least one of:
(a) a recirculation fan, different from the exchange fan, for recirculation inside the outdoor box of the inside air, or
(b) a further exchange fan for exchange of the outside air and the inside air, wherein the exchange fan is designed for being supplied with electrical power at least for the most part by an energy source, and wherein the further exchange fan is designed for being supplied with electrical power at least for the most part by a further energy source, different from the energy source.

2. The outdoor box according to claim 1,
wherein the outdoor box is a transporting outdoor box and/or a mobile outdoor box, and/or
wherein the outdoor box is designed so as to be fastenable on a loading area of a vehicle.

3. The outdoor box according to claim 1,
wherein the outdoor box contains the charger.

4. The outdoor box according to claim 1,
wherein the electrical line has an electricity mains connection, and
wherein the electrical line is designed for transmission of electrical power from the electricity mains connection to the recirculation fan and/or the further exchange fan.

5. The outdoor box according to claim 1, further comprising:
a radiation-energy conversion device for supplying the exchange fan, independently of an inside temperature of the inside air and/or an outside temperature of the outside air, with electrical power.

6. The outdoor box according to claim 5, further comprising:
an electrical energy store for supplying the exchange fan, independently of an inside temperature of the inside air and/or an outside temperature of the outside air, with electrical power from the radiation-energy conversion device.

7. The outdoor box according to claim 6, further comprising:
a box container; and
a box lid,
wherein the box container is designed for keeping the battery pack and at least for receiving the charger, and wherein at least one of: the electrical line, the recirculation fan, or the further exchange fan, is arranged on the box container,
wherein, for opening and closing the box container, the box lid is movable with respect to the box container, and wherein at least one of: the exchange fan, the radiation-energy conversion device, or the electrical energy store, is arranged on the box lid.

8. The outdoor box according to claim 7, further comprising:
at least one air inlet opening for letting the outside air into the outdoor box; and
at least one air outlet opening for letting the inside air out of the outdoor box,
wherein the air outlet opening is positioned above in relation to the air inlet opening in a vertical direction from an underside to an upper side of the outdoor box, and is offset in a horizontal direction orthogonal to the vertical direction.

9. The outdoor box according to claim 8,
wherein the air outlet opening is on the box lid, and/or
wherein the air inlet opening is on the underside and/or a peripheral side of the box container.

10. The outdoor box according to claim 1, further comprising:
at least one air inlet opening for letting the outside air into the outdoor box, and/or
at least one air outlet opening for letting the inside air out of the outdoor box,
wherein the outdoor box is designed for keeping the battery pack and/or at least for receiving the charger in relation to the air inlet opening and/or the air outlet opening above in a vertical direction from an underside to an upper side of the outdoor box, and/or offset in a horizontal direction orthogonal to the vertical direction.

11. The outdoor box according to claim 1, further comprising:
at least one air inlet opening for letting the outside air into the outdoor box, and/or
at least one air outlet opening for letting the inside air out of the outdoor box,
wherein the exchange fan and/or the further exchange fan is in the air inlet opening or the air outlet opening and is at an exchange distance from said opening along an air flow path, and
wherein a recirculation distance of the recirculation fan along an air flow path from the air inlet opening and/or the air outlet opening is greater than the exchange distance.

12. The outdoor box according to claim 1, wherein at least one of:
the exchange fan is aligned for delivering an air flow substantially in a first direction from an underside to an upper side of the outdoor box, or
the recirculation fan is aligned for delivering an air flow substantially in a second direction, different from the first direction, or
the further exchange fan is aligned for delivering an air flow substantially in a third direction, different from the first direction and/or the second direction.

13. The outdoor box according to claim 12, wherein
the first direction is a vertical direction, and
the second direction is orthogonal to the first direction, and the third direction is orthogonal to the first and/or second direction.

14. The outdoor box according to claim 1, further comprising:
a heater and/or a cooler, and
wherein the recirculation fan is designed for recirculating the inside air along the heater and/or the cooler.

15. The outdoor box according to claim 14, further comprising:
an open-loop and/or closed-loop control device for open-loop and/or closed-loop control of operation of the recirculation fan and of the heater and/or the cooler, and/or of the further exchange fan, dependent on an inside temperature, detected by an inside temperature sensor of the outdoor box, of the inside air and/or an outside temperature, detected by an outside temperature sensor of the outdoor box, of the outside air,
in such a way that the inside temperature reaches and/or exceeds a minimum temperature value, and/or reaches and/or falls below a maximum temperature value.

16. A system, comprising:
an outdoor box according to claim 1; and
at least one of: the battery pack, the charger, the garden, forestry, construction and/or ground working apparatus, or a vehicle.

17. A method for supplying a battery pack with electrical charging power by a charger, which comprises utilizing the outdoor box of claim 1.
